(19) United States
(12) Patent Application Publication
(10) Pub. No.: US 2022/0208522 A1
(43) Pub. Date: Jun. 30, 2022

(54) PLASMA JET SOLID ABLATION-BASED DIRECT ANALYSIS APPARATUS

(71) Applicant: CHENGDU ALIEBN SCIENCE AND TECHNOLOGY CO., LTD, Chengdu, Sichuan (CN)

(72) Inventors: Yanting YANG, Chengdu, Sichuan (CN); Zhuo LIU, Chengdu, Sichuan (CN); Jianxiong DAI, Chengdu, Sichuan (CN)

(21) Appl. No.: 17/428,098

(22) PCT Filed: Dec. 13, 2018
(86) PCT No.: PCT/CN2018/120782

§ 371 Date: Mar. 14, 2022

(30) Foreign Application Priority Data
Jul. 16, 2018 (CN) 201810779779.X

(51) Int. Cl. H01J 37/32

(52) U.S. Cl. CPC H01J 37/32211; H01J 37/3244; H01J 2237/0817; H01J 2237/141; H01J 37/32266

(57) ABSTRACT

An apparatus for direct analysis is based on solid ablation by a plasma jet. It includes a microwave plasma system, a gas transmission system, a sample carrying system, a signal collection system and a data analysis system. In the microwave plasma system both the microwave resonant cavity and the discharge tube are connected to the microwave power source. The gas transmission system is connected to the discharge tube; the sample carrying system is located below a gas outlet of the discharge tube. The signal collection system is configured to collect a spectral signal of a sample to be tested, and is connected to the data analysis system.

### TECHNICAL FIELD

The present disclosure relates to the technical field of direct sample analysis, in particular to an apparatus for direct analysis based on solid ablation by a plasma jet.

### BACKGROUND

Traditional analysis of a solid sample requires wet digestion, that is, the solid sample must be crushed, ground and digested before analysis. Due to complexity of a pretreatment process, an analysis process often takes a long time, so it is difficult to use this method for rapid detection of samples on site. Moreover, the method may also introduce uncertain factors in the analysis process, which increases the uncertainty of the method, and thus affects the accuracy and stability of analysis results. In addition, as a digestion process of a solid sample often needs to use dangerous chemical reagents such as perchloric acid, concentrated nitric acid and caustic soda, it does not meet the requirements of green analysis of samples.

Direct sample introduction analysis of a sample can solve the above problems to a large extent. Direct sample analysis is an important part of modern analytical science, and commonly used methods include laser ablation, electrothermal vaporization sample introduction and electric spark ablation. However, as an analysis apparatus for these methods includes components such as a graphite furnace, a laser and an electric heater, the entire apparatus is very complicated, and also cannot meet the requirement of on-site rapid detection. An X-ray diffractometer, which has developed rapidly in recent years, has a simple structure and can achieve on-site rapid detection of samples, but the apparatus is low in sensitivity, and inadequate in the ability of simultaneous analysis of multiple elements, making it difficult to detect light elements in samples.

In view of the above problems, the present disclosure provides an apparatus for direct analysis based on solid ablation by a plasma jet, which has a simple structure and high sensitivity, and can achieve simultaneous detection of multiple elements in a single sample. The apparatus includes a microwave resonant cavity. Microwave energy is coupled to a working gas through the microwave resonant cavity to generate microwave plasma; after the microwave plasma is ignited, a microwave plasma jet is formed, and the sample is ablated by a tail flame of the microwave plasma jet, and a spectral signal generated during the ablation of the sample is collected, so that qualitative and quantitative analysis can be carried out on elements in the sample. During working of an existing apparatus for direct analysis based on solid ablation by a plasma jet, an operator needs to carry out manual ignition by holding a metal wire in hand near a microwave resonant cavity to ignite microwave plasma. Obviously, this ignition method not only is inconvenient to operate, but also has a risk of microwave leakage; moreover, to successfully ignite the microwave plasma, the diameter of a discharge tube in the microwave resonant cavity cannot be made too small. These shortcomings greatly limit applications of microwave plasma.

### SUMMARY

The present disclosure is intended to provide an apparatus for direct analysis based on solid ablation by a plasma jet, which is capable of achieving an automatic ignition process of microwave plasma, thereby greatly improving the use convenience of the apparatus.

To achieve the above object, the present disclosure adopts the following technical solution: An apparatus for direct analysis based on solid ablation by a plasma jet includes a microwave plasma system, a gas transmission system, a sample carrying system, a signal collection system, and a data analysis system, wherein the microwave plasma system includes a microwave resonant cavity, a microwave power source, and a discharge tube axially penetrating through the microwave resonant cavity; both the microwave resonant cavity and the discharge tube are connected to the microwave power source; the gas transmission system is connected to the discharge tube; the sample carrying system is located below a gas outlet of the discharge tube; the signal collection system is configured to collect a spectral signal of a sample to be tested; the signal collection system is connected to the data analysis system; the apparatus further includes an ignition device; the ignition device includes a high-voltage power supply device and two discharge needles; pointed ends of the two discharge needles penetrate through the side wall of the discharge tube and are located in the discharge tube, and the pointed ends of the two discharge needles are opposite; and tail ends of the two discharge needles are connected to the output end of the high-voltage power supply device.

Further, the microwave plasma system further includes a microwave antenna; a coupling piece of the microwave antenna is arranged on the discharge tube located inside the microwave resonant cavity, and the microwave antenna is connected to the microwave power source through a microwave transmission line; the gas transmission system includes a gas cylinder and a gas path pipe, wherein the gas path pipe connects the gas cylinder with a gas inlet of the discharge tube; the gas path pipe is provided with a pressure gauge and a flow control gauge; the sample carrying system is a three-dimensional moving platform; the signal collection system includes a focusing lens and a spectrometer; the focusing lens is located above the three-dimensional moving platform, and the focusing lens and the spectrometer are connected by an optical fiber; the data analysis system includes an upper computer; and the upper computer is connected to the spectrometer.

Further, the discharge tube is further provided with two branch tubes; the two branch tubes are located between the gas inlet of the discharge tube and the top of the microwave resonant cavity, the two branch tubes are located on the same straight line, and the two branch tubes are perpendicular to the discharge tube; and the pointed ends of the two discharge needles respectively penetrate through the two branch tubes and are located in the discharge tube.

Preferably, the high-voltage power supply device is a Tesla coil; and the material of the discharge needles is copper or tungsten or stainless steel.

Further, the apparatus further includes a controller, wherein the input end of the controller is connected to the upper computer, and the output end of the controller is connected to the high-voltage power supply device.

Further, the apparatus further includes a camera, wherein the camera is arranged on the gas outlet side of the discharge tube, and the camera is connected to the upper computer.

Further, the apparatus further includes more than one sample matrix; the sample matrices are arranged in an array on a sample plate of the three-dimensional moving platform; the sample plate is made of a non-metallic high-temperature-resistant material; and the sample matrix is made of a flammable, water-absorbing material.

Preferably, the material of the sample plate is ceramic or graphite or quartz, and the thickness of the sample plate is 0.5-5 mm; the sample matrix is filter paper or mask paper or fiber filter membrane; the area of one sample matrix is 1-20 mm²; an included angle between the discharge tube and the sample plate is 30°-90°; and an included angle between a main optical axis of the focusing lens and the sample plate is 30°-90°.

Further, the gas outlet of the discharge tube, the three-dimensional moving platform and the focusing lens are all arranged in one chamber; the chamber is provided with a gas discharge pipe; and an HEPA filter net is arranged in the gas discharge pipe.

Further, a heat dissipation fan is further arranged on one side of the outside of the microwave resonant cavity.

In the apparatus for direct analysis based on solid ablation by a plasma jet provided by the embodiment of the present disclosure, an ignition device is added on the basis of the existing apparatus, and the ignition device includes a high-voltage power supply device and two discharge needles. High-voltage power is supplied to the two discharge needles by the high-voltage power supply device to enable the two discharge needles to continuously discharge therebetween to generate seed electrons. The seed electrons enter the plasma tube located inside the microwave resonant cavity under the gas flow action of the working gas, i.e. entering a plasma discharge area, thereby igniting the microwave plasma. In addition, adding of the controller can achieve the purpose of directly controlling on the upper computer the on and off of the high-voltage power supply device, which further facilitates the operation. Thus, compared with an apparatus for direct analysis based on solid ablation by a plasma jet in the prior art, the technical solution provided by the present disclosure can achieve an automatic ignition process of microwave plasma, thereby greatly improving the use convenience of the apparatus.

### BRIEF DESCRIPTION OF THE DRAWINGS

FIG. 1 is a structural diagram of an embodiment of the present disclosure;

FIG. 2 is a structural diagram of an ignition device in an embodiment of the present disclosure;

FIG. 3 is a discharge schematic diagram of a Tesla coil in an embodiment of the present disclosure;

FIG. 4 is a structural diagram of logic control of a Tesla coil by using a relay and an acquisition card in an embodiment of the present disclosure;

FIG. 5 is a structural diagram of arrangement of sample matrices on a sample plate in an embodiment of the present disclosure;

FIG. 6 is an emission spectrum diagram of direct analysis and detection of a soil sample by the apparatus of the present disclosure;

FIG. 7 is an emission spectrum diagram of direct analysis and detection of a mixed standard solution by the apparatus of the present disclosure;

FIG. 8 is a standard curve diagram of elements Cu, Pb and Cr in a soil sample detected by the apparatus of the present disclosure; and

FIG. 9 is a standard curve diagram of an element Cd in a rice sample detected by the apparatus of the present disclosure.

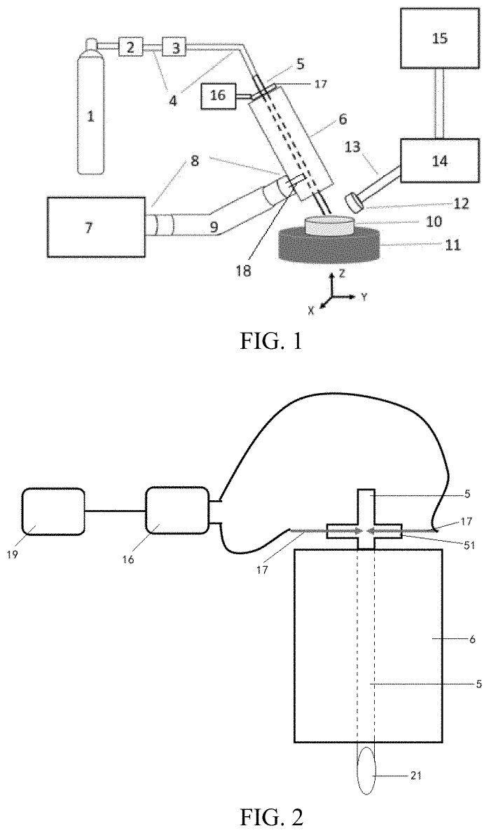

In FIG. 1, 1 denotes gas cylinder, 2 denotes pressure gauge, 3 denotes flow control gauge, 4 denotes gas path pipe, 5 denotes discharge tube, 51 denotes branch tube of discharge tube, 6 denotes microwave resonant cavity, 7 denotes microwave power source, 8 denotes interface of microwave transmission line, 9 denotes microwave transmission line, 10 denotes solid sample, 11 denotes three-dimensional moving platform, 101 denotes sample plate, 12 denotes focusing lens, 13 denotes optical fiber, 14 denotes spectrometer, 15 denotes upper computer, 16 denotes high-voltage power supply device, 17 denotes discharge needle, 18 denotes microwave antenna, 19 denotes controller, 109 denotes relay, 119 denotes data acquisition card, 20 denotes sample matrix, and 21 denotes microwave plasma jet.

### DETAILED DESCRIPTION

To make the objectives, technical solutions and advantages of the present disclosure clearer, the present disclosure will be further described in detail below in conjunction with the accompanying drawings.

FIG. 1 is a structural diagram of an embodiment of the present disclosure, including a microwave plasma system, a gas transmission system, a sample carrying system, a signal collection system and a data analysis system, wherein the microwave plasma system includes a microwave resonant cavity 6, a microwave power source 7, and a discharge tube 5 axially penetrating through the microwave resonant cavity 6; both the microwave resonant cavity 6 and the discharge tube 5 are connected to the microwave power source 7; the gas transmission system is connected to the discharge tube 5; the sample carrying system is located below a gas outlet of the discharge tube 5; the signal collection system is configured to collect a spectral signal of a sample to be tested; the signal collection system is connected to the data analysis system; the apparatus further includes an ignition device; the ignition device includes a high-voltage power supply device 16 and two discharge needles 17; pointed ends of the two discharge needles 17 penetrate through the side wall of the discharge tube 5 and are located in the discharge tube 5, and the pointed ends of the two discharge needles 17 are opposite; and tail ends of the two discharge needles 17 are connected to the output end of the high-voltage power supply device 16.

A specific composition and connecting mode of the above system are as follows: the microwave plasma system includes: the microwave resonant cavity 6, the microwave power source 7, a microwave antenna 18, and the discharge tube 5 axially penetrating through the microwave resonant cavity 6; a coupling piece of the microwave antenna 18 is arranged on the discharge tube 5 located inside the microwave resonant cavity 6, and the microwave antenna 18 is connected to the microwave power source 7 through a microwave transmission line 9; the microwave transmission line 9 is a coaxial cable or rectangular waveguide with an impedance of 50Ω; and the power of the microwave power source 7 is 50-200 W. The gas transmission system includes a gas cylinder 1 and a gas path pipe 4, wherein the gas path pipe 4 connects the gas cylinder 1 with a gas inlet of the discharge tube 5; the gas path pipe 4 is provided with a pressure gauge 2 and a flow control gauge 3; the sample carrying system includes a three-dimensional moving platform 11, and the three-dimensional moving platform 11 is located below the gas outlet of the discharge tube 5; the signal collection system includes a focusing lens 12 and a spectrometer 14; the focusing lens 12 is located above the three-dimensional moving platform 11, and the focusing lens 12 and the spectrometer 14 are connected by an optical fiber 13; the data analysis system includes an upper computer 15; the upper computer 15 is connected to the spectrometer 14; the apparatus further includes an ignition device; the ignition device includes a high-voltage power supply device 16 and two discharge needles 17; pointed ends of the two discharge needles 17 penetrate through the side wall of the discharge tube 5 and are located in the discharge tube 5, and the pointed ends of the two discharge needles 17 are opposite; and tail ends of the two discharge needles 17 are connected to the output end of the high-voltage power supply device 16. Microwave energy is transmitted to the microwave resonant cavity through the microwave transmission line, and is coupled to the discharge tube located inside the microwave resonant cavity through the microwave antenna. The microwave energy interacts with a working gas transmitted from the gas cylinder into the discharge tube to form microwave plasma. The discharge needles continuously discharge under the action of the high-voltage power supply device to generate seed electrons. The seed electrons enter a plasma discharge area under the gas flow action of the working gas, thereby igniting the microwave plasma to form a microwave plasma jet which is then ejected from the gas outlet of the discharge tube. The plasma ignition lasts for 1-3 s. By enabling a tail flame of the microwave plasma jet to act on the sample on the three-dimensional moving platform, the spectral signal generated during ablation of the sample can be collected to perform qualitative and quantitative analysis of elements in the sample.

The signal collection system in this embodiment includes the focusing lens, the optical fiber and the spectrometer, and can achieve spectrum detection with a resolution of 0.1-0.2 nm in the range of 200 nm to 800 nm. The data analysis system includes the upper computer installed with data processing software. Acquired spectrum data are processed by wavelet transform, least square fitting, iterative fitting and other algorithms to achieve baseline deduction, automatic peak seeking and automatic drawing of a standard curve.

In this embodiment, the discharge tube 5 is made of an inorganic insulating material, preferably quartz, or ceramic, or glass, or aluminum oxide. The discharge tube has an outer diameter of 6 mm or 8 mm and an inner diameter of 0.5-4 mm. The plasma working gas may be argon, helium, nitrogen, air, etc., with a flow rate of 0-1 L/min.

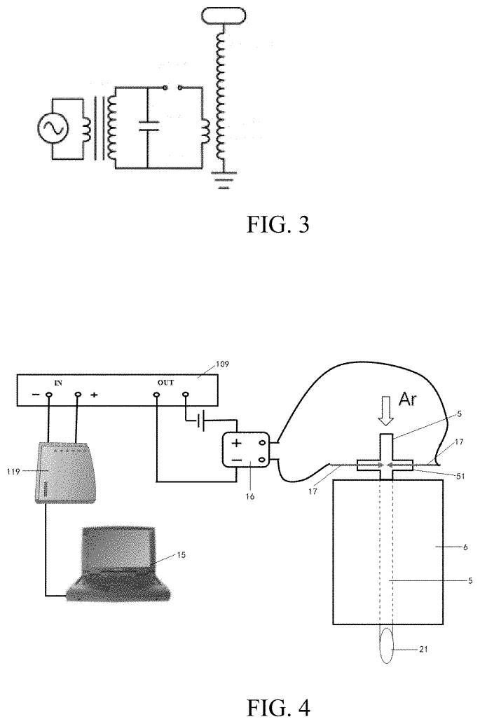

To effectively fix the two discharge needles, the discharge tube 5 is further provided with two branch tubes 51; the two branch tubes 51 are located between the gas inlet of the discharge tube 5 and the top of the microwave resonant cavity 6, the two branch tubes 51 are located on the same straight line, and the two branch tubes 51 are perpendicular to the discharge tube 5; and the pointed ends of the two discharge needles 17 respectively penetrate through the two branch tubes 51 and are located in the discharge tube 5. In this embodiment, the high-voltage power supply device 16 is a Tesla coil, a discharge schematic diagram of which is shown in FIG. 3; and the material of the discharge needles 17 is copper, tungsten or stainless steel, or other metal material that can be used for discharge. The distance between the discharge needles and the gas inlet of the discharge tube is 1-4 mm.

To further improve the convenience of operation and directly implement ignition by apparatus on the upper computer, this embodiment further includes a controller 19; the input end of the controller 19 is connected to the upper computer 15, and the output end of the controller 19 is connected to the high-voltage power supply device 16. A programmable controller may be directly used as the controller to control the on and off of the Tesla coil. Alternatively, to reduce equipment costs, a relay and a data acquisition card may also be used to achieve logic control of the Tesla coil, and a specific connecting mode is that: the input end of the data acquisition card is connected to the upper computer, and the output end of the data acquisition card is connected to the input end of the relay, and the output end of the relay is connected to the Tesla coil. The data acquisition card has a switching quantity output port which can output 0 and 5V control signals to the relay, and thus can control the on and off of the relay, thereby controlling the on and off of the Tesla coil, so as to achieve an ignition operation of the entire apparatus. In this case, the function of the data acquisition card is only to output a switching quantity to control the on and off of the relay.

In order to be able to directly observe on the upper computer whether the microwave plasma is successfully ignited, this embodiment further includes a camera; the camera is arranged on the gas outlet side of the discharge tube 5 to capture an ignition state of the microwave plasma; and the camera is connected to the upper computer 15 so as to transmit a captured image to the upper computer 15.

In addition to being used for direct analysis of a solid sample, the apparatus of the present disclosure may also be used for direct analysis of a liquid sample. To achieve direct analysis of a liquid sample, this embodiment further includes more than one sample matrix 20; the sample matrices 20 are arranged in an array on a sample plate 101 of the three-dimensional moving platform 11; the sample plate 101 is made of a non-metallic high-temperature-resistant material; and the sample matrix 20 is made of a flammable, water-absorbing material. Preferably, the material of the sample plate 101 is ceramic or graphite or quartz, and the thickness of the sample plate 101 is 0.5-5 mm; the sample matrix 20 is filter paper or mask paper or fiber filter membrane; and the sample matrix may be square, rectangular, circular or elliptical, and the area of one sample matrix is 1-20 mm². To analyze the liquid sample, 0.1-10 μL of liquid sample is accurately measured by a pipette and dropped onto the sample matrices, and the tail flame of the microwave plasma jet directly makes contact with the sample matrices, and the focusing lens is aligned with a part, in contact with the sample matrices, of the tail flame of the microwave plasma jet. Moisture in the sample evaporates and the sample matrices are dried and carbonized. The carbonized sample matrices are ablated in the tail flame of microwave plasma to burn. During this period, spectrum signals are continuously collected to perform qualitative and quantitative analysis on elements in the liquid sample.

When this apparatus is actually working, an included angle between the discharge tube 5 and the sample plate 101 is 30°-90°, preferably 30°; and an included angle between a main optical axis of the focusing lens 12 and the sample plate 101 is 30°-90°, preferably 30°. This apparatus can achieve fixed-point analysis and scanning analysis. Fixed-point analysis is suitable for analysis of involatile elements with high melting and boiling points. Scanning analysis is suitable for analysis of volatile elements with low melting and boiling points. During scanning analysis, the three-dimensional displacement platform moves at a speed of 0.1-1 mm/s, which, in combination with the rotation of the sample plate, allows the microwave plasma jet to continuously ablate different parts of the surface of the sample.

A tail gas clean-up device is further designed in this embodiment. Specifically, the gas outlet of the discharge tube 5, the three-dimensional moving platform 11 and the focusing lens 12 are all arranged in one chamber; the chamber is provided with a gas discharge pipe; and an HEPA filter net is arranged in the gas discharge pipe.

In this embodiment, a heat dissipation fan is further arranged on one side of the outside of the microwave resonant cavity 6 to dissipate heat from the microwave resonant cavity.

A method for direct analysis of a solid/liquid sample using this apparatus is as follows:

Step 1, simple planishing treatment is performed on a solid sample and tableting treatment is performed on a powder sample to prepare a solid sample for testing; a liquid sample is dropped onto sample matrices by using a pipette to prepare a liquid sample for testing;

Step 2, the sample for testing is moved into contact with tail flame of the microwave plasma jet by the three-dimensional moving platform, and then the sample is moved to be continuously ablated by the microwave plasma jet, and spectral signals are continuously collected during this period; and

Step 3: an acquired atomic emission spectrum of the sample is compared with a spectrum diagram of a sample with known concentrations to obtain qualitative and quantitative analysis results of elements in the sample.

Analysis of a soil sample is used as an example below to illustrate the setting of various parameters of this apparatus and verify the effect of this apparatus:

Soil standard sample powder (a sample of GBW soil standard sample series, with element contents confirmed) is tableted to prepare a solid sample. A specific tableting method is as follows: 0.4 g of soil sample is taken and maintained under a pressure of 4 MPa for 2 minutes to obtain round tablets of a sample to be analyzed with a diameter of 13 mm and a thickness of 2 mm, and the tablets are placed into a desiccator to be tested.

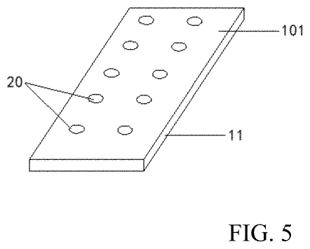

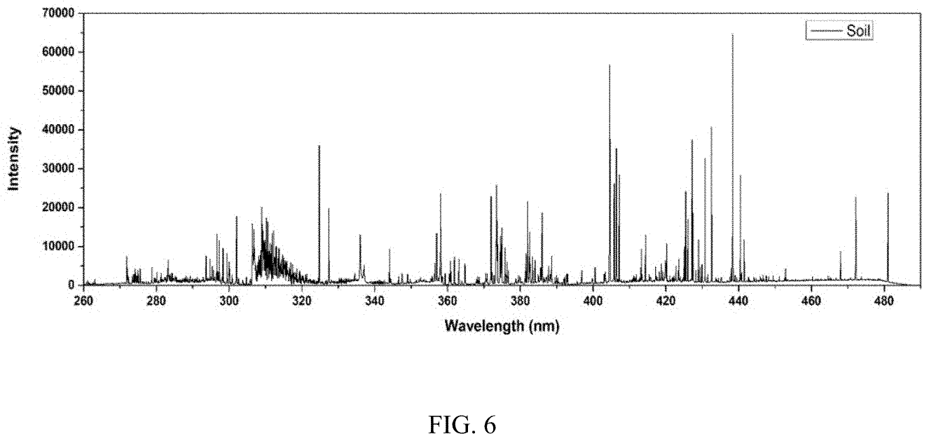

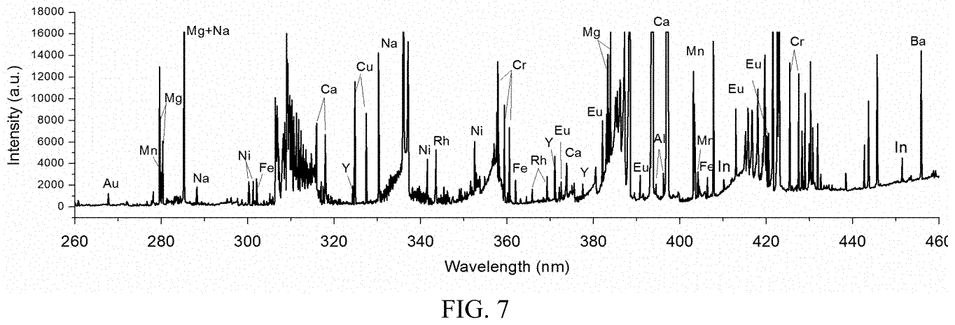

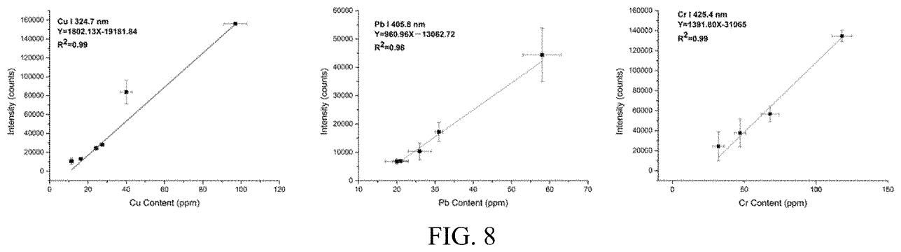

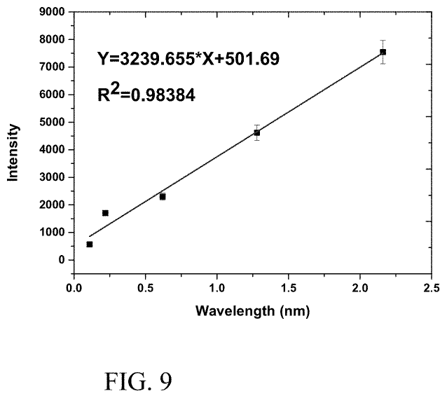

The working gas used in this experiment is argon with a purity of 99.999% and a gas flow rate set to 300 mL/min, and the microwave power source outputs a microwave of 2450 MHz in the form of a continuous wave, with an output power set to 150 W; the microwave transmission line is a coaxial cable with 50Ω impedance matching; the three-dimensional moving platform has a moving speed of 0.4 mm/s; and the spectrometer has integral time of 30 ms, and an averaging count of 1. An emission spectrum diagram of direct analysis and detection of the soil sample by the apparatus of the present disclosure is shown in FIG. 5, and a standard curve diagram of elements Cu, Pb, and Cr in the soil sample detected by the apparatus of the present disclosure is shown in FIG. 7.

It can be seen that not only can this apparatus accurately and rapidly analyze element contents in the sample, but also, due to the addition of the ignition device, the heat dissipation device and the tail gas clean-up device, the existing apparatus is further improved, so that the operational convenience of the apparatus is greatly improved.

The above contents are only specific implementations of the present disclosure, but the protection scope of the present disclosure is not limited thereto, and all changes or substitutions that are readily conceivable to those skilled in the art within the technical scope disclosed by the present disclosure should be encompassed within the protection scope of the present disclosure.

1. An apparatus for direct analysis based on solid ablation by a plasma jet, comprising a microwave plasma system, a gas transmission system, a sample carrying system, a signal collection system and a data analysis system, wherein the microwave plasma system comprises a microwave resonant cavity (6), a microwave power source (7), and a discharge tube (5) axially penetrating through the microwave resonant cavity (6); both the microwave resonant cavity (6) and the discharge tube (5) are connected to the microwave power source (7); the gas transmission system is connected to the discharge tube (5); the sample carrying system is located below a gas outlet of the discharge tube (5); the signal collection system is configured to collect a spectral signal of a sample to be tested; the signal collection system is connected to the data analysis system; the apparatus further comprises an ignition device; the ignition device comprises a high-voltage power supply device (16) and two discharge needles (17); pointed ends of the two discharge needles (17) penetrate through a side wall of the discharge tube (5) and are located in the discharge tube (5), and the pointed ends of the two discharge needles (17) are opposite; and tail ends of the two discharge needles (17) are connected to an output end of the high-voltage power supply device (16).

2. The apparatus for direct analysis based on solid ablation by a plasma jet according to claim 1, wherein the microwave plasma system further comprises a microwave antenna (18); a coupling piece of the microwave antenna (18) is arranged on the discharge tube (5) located inside the microwave resonant cavity (6), and the microwave antenna (18) is connected to the microwave power source (7) through a microwave transmission line (9); the gas transmission system comprises a gas cylinder (1) and a gas path pipe (4), wherein the gas path pipe (4) connects the gas cylinder (1) with a gas inlet of the discharge tube (5); the gas path pipe (4) is provided with a pressure gauge (2) and a flow control gauge (3); the sample carrying system is a three-dimensional moving platform (11); the signal collection system comprises a focusing lens (12) and a spectrometer (14); the focusing lens (12) is located above the three-dimensional moving platform (11), and the focusing lens (12) and the spectrometer (14) are connected by an optical fiber (13); the data analysis system comprises an upper computer (15); and the upper computer (15) is connected to the spectrometer (14).

3. The apparatus for direct analysis based on solid ablation by a plasma jet according to claim 2, wherein the discharge tube (5) is further provided with two branch tubes (51); the two branch tubes (51) are located between the gas inlet of the discharge tube (5) and the top of the microwave resonant cavity (6), the two branch tubes (51) are located on the same straight line, and the two branch tubes (51) are perpendicular to the discharge tube (5); and the pointed ends of the two discharge needles (17) respectively penetrate through the two branch tubes (51) and are located in the discharge tube (5).

4. The apparatus for direct analysis based on solid ablation by a plasma jet according to claim 3, wherein the high-voltage power supply device (16) is a Tesla coil; a material of the discharge needle (17) is copper or tungsten or stainless steel; and the discharge tube (5) is made of an inorganic insulating material.

5. The apparatus for direct analysis based on solid ablation by a plasma jet according to claim 2, further comprising a controller (19), wherein an input end of the controller (19) is connected to the upper computer (15), and an output end of the controller (19) is connected to the high-voltage power supply device (16).

6. The apparatus for direct analysis based on solid ablation by a plasma jet according to claim 5, further comprising a camera, wherein the camera is arranged on a gas outlet side of the discharge tube (5), and the camera is connected to the upper computer (15).

7. The apparatus for direct analysis based on solid ablation by a plasma jet according to claim 2, further comprising more than one sample matrix (20), wherein the sample matrices (20) are arranged in an array on a sample plate (101) of the three-dimensional moving platform (11); the sample plate (101) is made of a non-metallic high-temperature-resistant material; and the sample matrix (20) is made of a flammable, water-absorbing material.

8. The apparatus for direct analysis based on solid ablation by a plasma jet according to claim 7, wherein a material of the sample plate (101) is ceramic or graphite or quartz, and a thickness of the sample plate (101) is 0.5-5 mm; the sample matrix (20) is filter paper or mask paper or fiber filter membrane; an area of one sample matrix (20) is 1-20 mm²; an included angle between the discharge tube (5) and the sample plate (101) is 30°-90°; and an included angle between a main optical axis of the focusing lens (12) and the sample plate (101) is 30°-90°.

9. The apparatus for direct analysis based on solid ablation by a plasma jet according to claim 2, wherein the gas outlet of the discharge tube (5), the three-dimensional moving platform (11) and the focusing lens (12) are all arranged in one chamber; the chamber is provided with a gas discharge pipe; and an HEPA filter net is arranged in the gas discharge pipe.

10. The apparatus for direct analysis based on solid ablation by a plasma jet according to claim 2, wherein a heat dissipation fan is further arranged on one side of the outside of the microwave resonant cavity (6).
